(19) United States
(12) Patent Application Publication
(10) Pub. No.: US 2026/0092364 A1
(43) Pub. Date: Apr. 2, 2026

(54) METHODS FOR DEPOSITING METAL NITRIDE LAYERS ON A SUBSTRATE BY CYCLICAL DEPOSITION PROCESSES INCLUDING CYCLIC COMPOUNDS

(71) Applicant: ASM IP Holding B.V., Almere (NL)

(72) Inventors: Mikko Leander Nisula, Espoo (FI); Charles Dezelah, Helsinki (FI); Petro Deminskyi, Espoo (FI); Hoang Nguyen, Espoo (FI); Patricio Eduardo Romero, Boutersem (BE); Emre Yarali, Helsinki (FI); Giuseppe Alessio Verni, Ismaning (DE); Jocelyn Kofi Brobbey, Phoenix, AZ (US); Serges Zambou, Espoo (FI); Ranjith Karuparambil Ramachandran, Leuven (BE); Aditya Chauhan, Ottignies-Louvain-Ia-Neuve (BE); Andrea Illiberi, Leuven (BE); Alessandra Leonhardt, Sipoo (FI)

(21) Appl. No.: 19/343,820

(22) Filed: Sep. 29, 2025

Related U.S. Application Data
(60) Provisional application No. 63/701,067, filed on Sep. 30, 2024.

(51) Int. Cl. C23C 16/455; C23C 16/34; C23C 16/46; H01L 21/02; H01L 21/3205; H01L 21/768

(52) U.S. Cl. CPC C23C 16/45527; C23C 16/34; C23C 16/45553; C23C 16/46; H10P 14/412; H10P 14/69392; H10W 20/032

(57) ABSTRACT

Methods of depositing metal nitride layers employing low temperature cyclical deposition processes including cyclic compounds are disclosed. The cyclical deposition processes include repeatedly performing a deposition cycle including introducing a metal precursor into a reaction chamber, introducing a nitrogen reactant into the reaction chamber, and introducing a reducing agent comprising a cyclic compound into the reaction chamber. Metal nitride layers and semiconductor structures including metal nitride layers are also disclosed.

### CROSS-REFERENCE TO RELATED APPLICATION(S)

This Application claims the benefit of U.S. Provisional Application 63/701,067 filed on Sep. 30, 2024, the entire contents of which are incorporated herein by reference.

### FIELD

The present disclosure relates generally to the field of semiconductor processing methods, associated structures and to the field of device and integrated circuit manufacture. More particularly the present disclosure generally relates to methods for depositing metal nitride layers on a substrate, layers comprising a metal nitride, and structures including metal nitride layers.

### BACKGROUND

Semiconductor device fabrication processes generally use advanced deposition methods for forming metal-containing layers with specific properties. Metal nitrides in groups 4 (titanium, zirconium, hafnium), 5 (vanadium, niobium, tantalum) and 6 (chromium, molybdenum, and tungsten) are potentially useful for a range of semiconductor applications. In particular, these materials are proposed for back-end-of line (BEOL) barrier and liner applications, where low electrical resistivity is important. Additionally, many applications require low temperature deposition of these materials due to integration thermal budget limitations.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments provided include a method for depositing a metal nitride layer on a substrate seated in a reaction chamber by a cyclical deposition process including one or more repeated deposition cycles, each deposition cycle comprising: (a) initially introducing a metal precursor into the reaction chamber; (b) introducing a nitrogen reactant into the reaction chamber; and (c) introducing a reducing agent comprising a cyclic compound into the reaction chamber; wherein step (c) is either performed after step (b) or step (c) is performed concurrently with step (b).

In some embodiments, the cyclical deposition process is an atomic layer deposition process and each deposition cycle comprises: (a) initially contacting the substrate with the metal precursor; after step (a), (b) contacting the substrate with the nitrogen reactant; and after step (b), (c) contacting the substrate with the cyclic compound.

In some embodiments, the cyclical deposition process is an atomic layer deposition process and each deposition cycle comprises: (a) initially contacting the substrate with the metal precursor; and after step (a), (b)(c) concurrently contacting the substrate with the nitrogen reactant and the cyclic compound.

In some embodiments, the cyclical deposition process is an atomic layer deposition process and each deposition cycle comprises a deposition super-cycle, each deposition super-cycle comprising: performing one or more first sub-cycles comprising: contacting the substrate with the metal precursor; and contacting the substrate with the nitrogen reactant; and performing one or more second sub-cycles comprising: contacting the substrate with the cyclic compound.

In some embodiments, the cyclic compound comprises a cyclic diene compound.

In some embodiments, the cyclic diene compound is selected from 1,4-cyclohexadiene, 1,3-cyclohexadiene, and 1-methyl-1,4-cyclohexadiene.

In some embodiments, the cyclic compound comprises a polycyclic hydrocarbon compound.

In some embodiments, the polycyclic hydrocarbon compound is selected from 1,2,3,4-tetrahydronaphthalene and 9,10-Dihydroanthracene.

In some embodiments, the metal precursor is selected from a titanium precursor, a molybdenum precursor, a hafnium precursor, and a niobium precursor.

In some embodiments, the cyclical deposition process is performed at a deposition temperature between 350° C. and 500° C.

Various embodiments provided include a method for thermally depositing a metal nitride layer on a substrate, the method comprising: heating the substrate to a deposition temperature between 350° C. and 500° C.; and repeatedly performing a deposition cycle of an atomic layer deposition process, each deposition cycle comprising: (a) initially contacting the substrate with a transition metal precursor; after contacting the substrate the transition metal precursor, (b) contacting the substrate with a nitrogen reactant; and after contacting the substrate with the nitrogen reactant, (c) contacting the substrate with a reducing agent comprising a cyclic diene compound selected from 1,4-cyclohexadiene, 1,3-cyclohexadiene, and 1-methyl-1,4-cyclohexadiene.

In some embodiments, the transition metal precursor is selected from a titanium halide precursor, and a molybdenum halide precursor.

In some embodiments, the molybdenum halide precursor comprises a molybdenum oxyhalide precursor.

Various embodiments provided include a method of forming a semiconductor structure, the method comprising: seating a substrate within a reaction chamber, the substrate including a metal oxide layer; heating the substrate to a deposition temperature between 350° C. and 500° C.; and depositing a metal nitride layer over the metal oxide layer by repeatedly performing a deposition cycle of an atomic layer deposition process, each deposition cycle comprising: (a) initially contacting the substrate with a metal precursor; after contacting the substrate the metal precursor, (b) contacting the substrate with a nitrogen reactant; and after contacting the substrate with the nitrogen reactant, (c) contacting the substrate with reducing agent comprising a cyclic diene compound selected from 1,4-cyclohexadiene, 1,3-cyclohexadiene, and 1-methyl-1,4-cyclohexadiene.

In some embodiments, the method further includes depositing a metal nitride interlayer directly on the metal oxide layer prior to depositing the metal nitride layer directly on the metal nitride interlayer.

In some embodiments, the metal nitride interlayer is deposited by a second atomic layer deposition process comprising sequentially and alternating contacting the substrate with the metal precursor and the nitrogen reactant.

In some embodiments, the metal nitride layer is a conductive layer and the metal nitride interlayer is an insulating layer.

In some embodiments, the metal nitride layer has a first stoichiometry and the metal nitride interlayer has a second stoichiometry, wherein the first stoichiometry and the second stoichiometry are different.

In some embodiments, the metal nitride layer comprises a first hafnium nitride layer and the metal nitride interlayer comprise a second hafnium nitride layer.

In some embodiments, the first hafnium nitride layer has a HfN stoichiometry and the second hafnium nitride layer has a Hf₃N₄ stoichiometry.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method of depositing a metal nitride layer in accordance with one or more embodiments of the disclosure.

FIG. 2 illustrates a deposition super-cycle for depositing a metal nitride layer in accordance with one or more embodiments of the disclosure.

FIG. 3 illustrates a first sub-cycle employed in the deposition of a metal nitride layer in accordance with one or more embodiments of the disclosure.

FIG. 4 illustrates a second sub-cycle employed in the deposition of a metal nitride layer in accordance with one or more embodiments of the disclosure.

FIG. 5 illustrates a substrate upon which a metal nitride layer is deposited in accordance with one or more embodiments of the disclosure.

FIG. 6 illustrates a structure including a substrate and a metal nitride layer deposited in accordance with one or more embodiments of the disclosure.

FIG. 7 illustrates a method of forming a structure including a metal nitride interlayer and a metal nitride layer in accordance with one or more embodiments of the disclosure.

FIG. 8 illustrates a structure including a substrate and a metal oxide layer in accordance with one or more embodiments of the disclosure.

FIG. 9 illustrates a structure including a substrate, a metal oxide layer, and a metal nitride interlayer in accordance with one or more embodiments of the disclosure.

FIG. 10 illustrates a structure including a substrate, a metal oxide layer, a metal nitride interlayer, and a metal nitride layer in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

As used herein, the terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

As used herein, the term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

Various embodiments of the present disclosure relate to methods for depositing metal nitride layers on a substrate, layers including metal nitrides, as well as structures including metal nitride layers. Various metal nitride layers can be employed in the fabrication of semiconductor devices and integrated circuits. For example, metal nitride layers can be employed as work functions metals, gate stack liners, capping materials, and the like.

Metal precursors commonly employed in the deposition of metal nitride layers may have a higher oxidation state than that of the stoichiometry of the desired metal nitride layer being deposited. Therefore, reduction of the metal element (i.e., the metal center) of the metal precursor during the deposition process can be employed. Commonly, during the deposition of metal nitrides, a nitrogen reactant can be employed as the nitrogen source/reducing agent. However, the nitrogen reactant alone may have insufficient reactivity at the desired deposition temperature. Therefore, at lower deposition temperatures (e.g., below 500° C.) the reduction of the metal component supplied by the metal precursor may be incomplete. The incomplete reduction of the metal component of the metal nitride layer may have a detrimental impact on the properties of the metal nitrides layers being deposited. For example, incomplete reduction may result in metal nitride layers with a high resistivity, as well as a higher concentration of undesirable impurities. Such detrimental effects can be problematic for certain applications/integration schemes which employ low thermal budgets.

According to various embodiments of the present disclosure, an additional co-reactant is employed during the cyclical deposition processes employed for depositing the metal nitride layers. The additional co-reactant may catalyze the reduction of the metal center which in turn can improve the properties of the metal nitride layers deposited by the methods disclosed herein. Various examples include methods for depositing metal nitride layers at a reduced deposition temperature, thereby reducing the thermal budget of the deposition processes employed in the fabrication of devices and integrated circuits including such layers. In addition, various examples include methods for depositing metal nitride layers at a reduced deposition temperature without a significant detrimental effect on the resistivity and/or the impurity concentration of the deposited metal nitride layers.

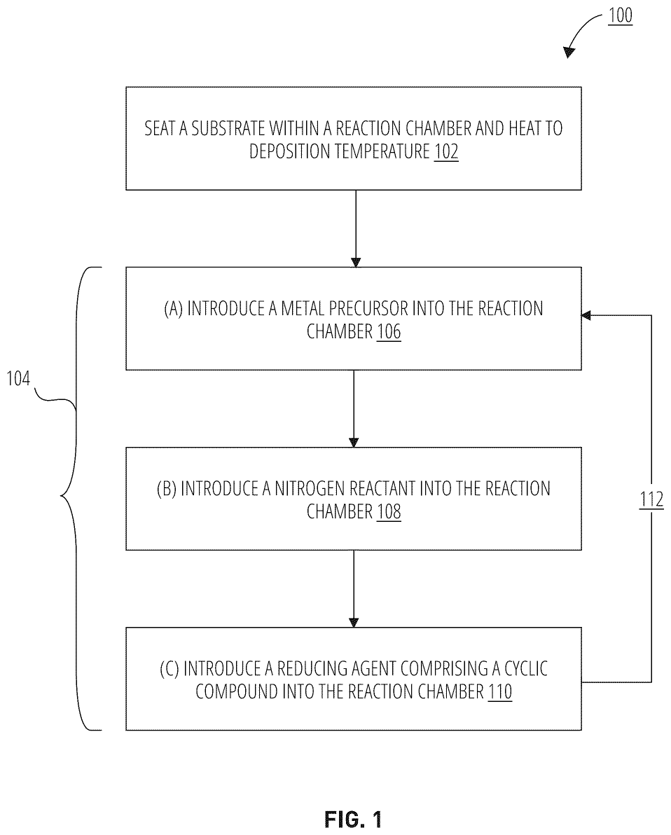

Turning now to the figures, FIG. 1 illustrates an exemplary method 100 for depositing a metal nitride layer. In brief method 100 may include seating a substrate within a reaction chamber and heating the substrate to the deposition temperature (step 102), and subsequently depositing a metal nitride layer on the substrate by employing a cyclical deposition process 104.

In accordance with examples of the disclosure the substrate upon which the metal nitride layer is deposited can comprise one or more partially fabricated device structures, such as, for example, logic elements and/or memory elements. In certain embodiments, the substrate may include a dielectric material, such as a high-k dielectric layer disposed on the surface of substrate, as described further below. The high-k dielectric layer may include materials having a dielectric constant greater than the dielectric constant of silicon dioxide, such as, for example, hafnium oxides, hafnium zirconium oxide, and the like.

In accordance with examples of the disclosure, the reaction chamber in which the substrate is seated for deposition can be, or include, a reaction chamber of semiconductor deposition apparatus configured for performing cyclical deposition processes, such as, an atomic layer deposition apparatus. The reaction chamber can be a standalone reaction chamber or part of a cluster tool. The reaction chamber may be part of a batch processing tool. In some embodiments, a flow-type reaction chamber may be utilized. In some embodiments, a showerhead-type reaction chamber may be utilized. In some embodiments, a space divided reaction chamber may be utilized. In some embodiments, a high-volume manufacturing-capable single wafer reaction chamber may be utilized. In other embodiments, a batch reaction chamber comprising multiple substrates may be utilized. For embodiments in which a batch reaction chamber is used, the number of substrates may be in the range of 10 to 200, or 50 to 150, or even 100 to 130. In various embodiments the substrate is seated in a reaction chamber configured as a thermal reactor—i.e., with no plasma excitation apparatus. Alternatively, the reaction chamber can include direct and/or remote plasma apparatus.

In accordance with examples of the disclosure, the substrate seated within the reaction chamber may be heated to a desired deposition temperature (i.e., the temperature of the substrate during the deposition of the metal nitride layer). In various embodiments the deposition temperature may less than 600° C., less than 450° C., less than 400° C., less than 350° C., less than 300° C., less than 250° C., or less than 200° C. In various embodiments the deposition temperature may be greater than room temperature, between 700° C. and 300° C., between 325° C. and 500° C., between 350° C. and 500° C., or between 350° C. and 450° C.

In accordance with examples of the disclosure, in addition to controlling the deposition temperature, the pressure in the reaction chamber may also be regulated to enable deposition of a metal nitride layer with desired layer properties. In such examples, the pressure within the reaction chamber may be less than 760 Torr, between 0.1 Torr and 10 Torr, between 0.5 Torr and 5 Torr, or between 1 Torr to 4 Torr.

In accordance with examples of the disclosure, the method 100 illustrated in FIG. 1 is employed for depositing a metal nitride layer on the substrate by performing one or more deposition cycles of a cyclical deposition process 104. In such examples, each deposition cycle of the cyclical deposition process 104 can comprise the steps of: introducing a metal precursor into the reaction chamber (step 106) (also referred to herein as step a), introducing a nitrogen reactant into the reaction chamber (step 108) (also referred to herein as step b), and introducing a reducing agent comprising a cyclic compound into the reaction chamber (step 110) (also referred to herein as step c).

In some embodiments step 106, step 108, and step 110 can be initiated and/or terminated in any order. In some embodiments step 106, step 108, and step 110 can be performed concurrently, or at least with some temporal overlap between the steps of the cyclical deposition process 104. In some embodiments the cyclical deposition process 104 can include one or more (e.g., 1-10 or 1-5) repetitions of each of steps 106, 108, 110 prior to proceeding to a subsequent step. In addition, the cyclical deposition process 104 may include one or more additional steps (not illustrated in FIG. 1). For example, the one or more additional steps may be performed during each deposition cycle of the cyclical deposition process 104 or alternatively may be performed during select cycles of the cyclical deposition process 104. A purging step (to remove excess precursor(s)/reactant(s) and any reaction byproducts from the reaction chamber) can be performed after having performed one or more of step 106, step 108, and step 110 and/or prior to and/or upon completion of each deposition cycle (as indicted by cycle loop 112).

In some embodiments the steps (i.e., steps a, b, and c) of each, or one or more, of the deposition cycles of the cyclical deposition process 104 may be performed in a particular sequence. It should be noted that the sequences described below may in addition include purge cycles upon completion of each process step.

In some embodiments each, or one or more of the deposition cycles, may comprise the sequence steps of: initially introducing a metal precursor into the reaction chamber (step 106), followed by introducing a nitrogen reactant into the reaction chamber (step 108), and introducing a reducing agent comprising a cyclic compound into the reaction chamber (step 110). Such a deposition cycle sequence may be denoted by the nomenclature a(b|c), where the brackets denote that both step b and step c are performed after having performed step a, and “|” denotes the logical operate “OR” indicating that either step b or step c may follow step a.

In some embodiments each, or one or more of the deposition cycles, may comprise the sequence steps of: initially introducing the metal precursor into the reaction chamber (step 106), followed subsequently by introducing the nitrogen reactant into the reaction chamber (step 108), followed subsequently by introducing the reducing agent comprising a cyclic compound into the reaction chamber (step 110). Such a deposition cycle sequence may be denoted by the nomenclature abc. In such embodiments the reducing agent comprising the cyclic compound is introduced into the reaction chamber after introducing the nitrogen reactant into the reaction chamber, (step 108). In other words, step 110 may be performed after step 108. In some examples the nitrogen reactant introduced into the reaction chamber forms a nitrided surface on the substrate. In such examples the nitrided surface is formed and subsequently contacted with the cyclic compound, e.g., by introducing the cyclic compounds into the reaction chamber following the nitrogen reactant. In such examples the cyclic compound can interact (e.g., react) with the previously formed nitrided surface on the substrate.

In some embodiments each, or one or more of the deposition cycles, may comprise the sequence steps of: initially introducing the metal precursor into the reaction chamber (step 106), followed by concurrently introducing the nitrogen reactant (step 108) and the reducing agent comprising the cyclic compound (step 110). In other words, step 108 and step 110 may be performed concurrently after the initial introduction of the metal precursor in step 106. Such a deposition cycle sequence may be denoted by the nomenclature a(b∧c), where the brackets denote that both step b and step c are performed after having performed step a, and “∧” denotes the logical operate “AND” indicating that step b and step c are performed concurrently. As used herein the term “concurrently” may refer to the co-flow of the reducing agent and the nitrogen reactant into the reaction chamber where there is at least a period of temporal overlap between the introduction of the reducing agent and the nitrogen reactant into the reaction chamber. In addition, as used herein, the term “concurrently” does not necessitate that step 108 and step 110 are initiated simultaneously and terminated simultaneously.

In some embodiments the cyclical deposition process 104 comprises an atomic layer deposition process and each deposition cycle comprises the steps 106, 108, 110 performed in the sequence of: initially contacting the substrate with the metal precursor (step 106), after having performed step 106, contacting the substrate with the nitrogen reactant (step 108), and after having performed step 108, contacting the substrate with the cyclic compound (step 110).

In some embodiments the cyclical deposition process 104 comprises an atomic layer deposition process and each deposition cycle comprises the steps 106, 108, 110 performed in the sequence of: initially contacting the substrate with the metal precursor (step 106), and after having performed step 106, concurrently contacting the substrate with the nitrogen reactant (step 108) and the reducing agent comprising the cyclic compound (step 110).

In some embodiments the metal nitride layer is deposited by cyclical deposition process comprising an atomic layer deposition process and each deposition cycle comprises a deposition super-cycle. In such embodiments each deposition super-cycle can include two or more sub-cycles which can each be performed one or more times to deposit the metal nitride layer on the substrate.

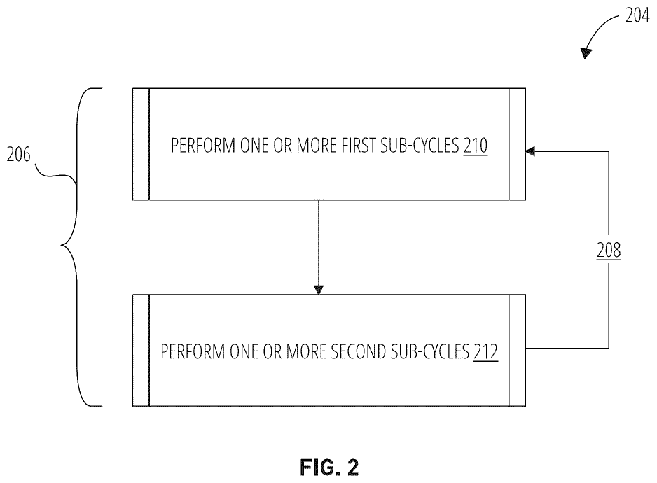

FIG. 2 illustrates a cyclical deposition process 204 comprising a deposition super-cycle 206 for depositing a metal nitride layer on a substrate. In such examples each deposition super-cycle 206 can be repeated one or more times, as indicated by super-cycle loop 208, and may comprise a first sub-cycle 210 and a second sub-cycle 212.

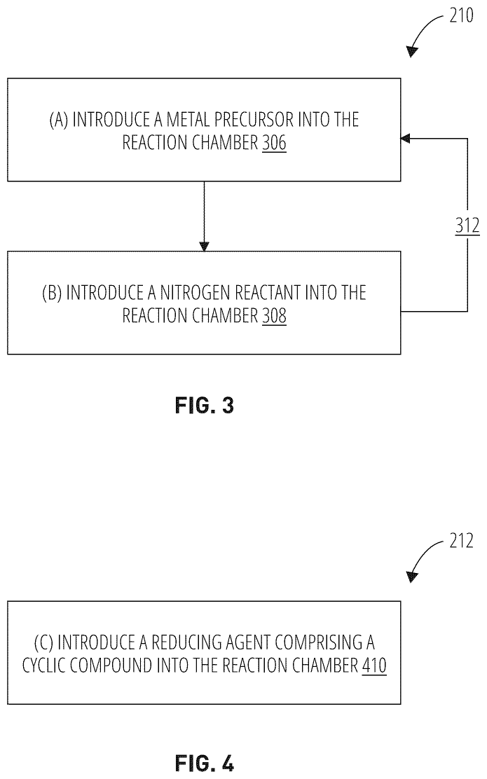

In various embodiments each first sub-cycle 210 (as illustrated in FIG. 3) may comprise, contacting the substrate with the metal precursor (sub-step 306), and contacting the substrate with nitrogen reactant (sub-step 308). The first sub-cycle 210 can be repeated one or more times as illustrated by the first sub-cycle loop 312, as desired within each deposition super-cycle 206. In some embodiments each first sub-cycle 210 can comprise, initially contacting the substrate with the metal precursor (sub-step 306), and subsequently contacting the substrate with the nitrogen reactant (sub-step 308).

In various embodiments each second sub-cycle 212 (as illustrated in FIG. 4) may comprise, contacting the substrate with the reducing agent comprising a cyclic compound (sub-step 410). The second sub-cycle 212 can be repeated one or more times as desired within each deposition super-cycle 206.

In accordance with examples of the disclosure, the reaction chamber may be purged while performing each sub-cycle 210, and 212, e.g., after each pulse of precursor/reactant and/or upon completion of sub-cycles 210, and 212, and/or after completion of a deposition super-cycle 206. In some embodiments the sub-cycles 210, and 212 can be repeated as illustrated by super-cycle loop 208. For example, the deposition super-cycle 206 can be performed 1 or more times, 2 or more times, 3 or more times, 5 or more times, 10 or more times, 25 or more times, or between 1 and 25 times.

In accordance with examples of the disclosure, the first sub-cycle 210 and second sub-cycle 212 may be initiated and/or terminated in any order, or in a specific sequence. In some embodiments the deposition super-cycle 206 can comprise initially performing the first sub-cycle 210 one or more times prior to performing the second sub-cycle 212 one or more times.

In various embodiments each deposition super-cycle 206 can include multiple repetitions of the first sub-cycle 210 and the second sub-cycle 212 prior to proceeding to the subsequent sub-cycle(s) of the deposition super-cycle 206. In some embodiments each deposition super-cycle 206 can also include one or more additional steps and/or sub-cycles which can performed during each deposition super-cycle 206 or during select deposition super-cycle 206 of the 204.

In some embodiments the properties of the metal nitride layer deposited employing cyclical deposition process 204 may be tuned by controlling the ratio of the number of times the first sub-cycle 210 is performed in relation to the number of times the second sub-cycle 212 is performed within each super-cycle loop 208 (i.e., the sub-cycle ratio). In some examples the sub-cycle ratio is selected to obtain a desired composition of the deposited metal nitride layer. For example, the sub-cycle ratio may be selected to deposit a metal rich metal nitride layer, or a nitrogen rich metal nitride layer.

The cyclical deposition processes of the present disclosure (e.g., 104, and 204) include introducing a metal precursor into the reaction chamber, such as during step 106 of cyclical deposition process 104, and during sub-step 306 of cyclical deposition process 204. In various embodiments the metal precursor can comprise a transition metal precursor.

In various embodiments the metal precursor includes a metal element (i.e., a metal center) having a first oxidation state and the metal nitride layer deposited by the cyclical deposition process (e.g., 104 and 204) includes the metal element having a second oxidation state, where the first oxidation state and the second oxidation state are different from one another.

In some embodiments the metal precursor comprises a metal selected from the transition metals. In such embodiments the metal precursor can comprises a transition metal selected from group 4 of the periodic table, including, for example, titanium, zirconium, and hafnium. In some embodiments the metal precursor can comprise a transition metal selected from group 5 of the periodic table, including, for example, vanadium, niobium, and tantalum. In some embodiments the metal precursor can comprise a transition metal selected from group 6 of the periodic table, including, for example, chromium, molybdenum, and tungsten.

In some embodiments the metal precursor comprises a metal halide precursor. In some embodiments the metal precursor comprises a metal oxyhalide precursor. In some embodiments the metal precursor comprises an organometallic precursor. In some embodiments the metal precursor comprises a halide-free metal precursor.

In some embodiments the metal precursor is selected from one or more of a titanium precursor, a molybdenum precursor, a hafnium precursor, and a niobium precursor. In some embodiments the metal precursor is selected from one or more of a titanium halide precursor, a molybdenum halide precursor, a hafnium halide precursor, and a niobium halide precursor. In some embodiments the metal precursor is selected from one or more of a titanium oxyhalide precursor, a molybdenum oxyhalide precursor, a hafnium oxyhalide precursor, and a niobium oxyhalide precursor. In some embodiments the metal precursor is selected from one or more of an organometallic titanium precursor, an organometallic molybdenum precursor, an organometallic hafnium halide precursor, and an organometallic niobium halide precursor.

In some embodiments the metal precursor comprises a molybdenum precursor including a molybdenum metal. In some examples the molybdenum precursor comprises a molybdenum halide, including but not limited to, MoCl₅, and MoCl₆. In some examples the molybdenum precursor comprises a molybdenum oxyhalide, including but not limited to MoOCl₃, MoOCl₄, and MoO₂Cl₂. In some examples the molybdenum precursor comprises an organometallic molybdenum precursor, including but not limited to, Mo(CO)₆, Mo(tBuN)₂(NMe₂)₂, Mo(NBu)₂(StBu)₂, (Me₂N)₄Mo, and (iPrCp)₂MoH₂.

In some embodiments the metal precursor comprises a titanium precursor including a titanium metal. In some examples the titanium precursor comprises a titanium halide, including but not limited to, TiCl₄, TiF₄, and TiI₄. In some examples the titanium precursor comprises a titanium organometallic precursor, including but not limited to, Ti(NEt₂)₄, Ti(NEtMe)₄, Ti(NMe₂)₄, TiCp₂((ⁱPrN)₂C(NHiPr)), Ti(Cp)CHT, Ti(CpMe)(OⁱPr)₃, Ti(CpMe₅)(OMe)₃, Ti(NEt₂)₄, Ti(NMe₂)₃(CpMe), and Ti(NMe₂)₃(CpN).

In some embodiments the metal precursor comprises a hafnium precursor including a hafnium metal. In some examples the hafnium precursor comprises a hafnium halide, including but not limited to HfCl₄, HfI₄, and HfBr₄. In some examples the hafnium precursor comprises an organometallic hafnium precursor, including but not limited to, Hf(NEtMe)₄, Hf(NMe₂)₄, Hf(NEt₂)₄, HfCp(NMe₂)₃, and (MeCp)₂Hf(CH)₃(OCH₃).

In some embodiments the metal precursor comprises a niobium precursor including a niobium metal. In some examples the niobium precursor comprises a niobium halide, including but not limited to, NbCl₅, and NbF₅. In some examples the niobium precursor comprises an organometallic niobium precursor, including but not limited to, Nb(N^{t}Bu)(NEt₂)₃, Nb(N^{t}Bu)(NEt₂)₂(Cp), Nb(N^{t}Bu)(NEtMe)₃, Nb(OEt)₅, and Nb(OEt)₅.

The cyclical deposition process of the present disclosure (e.g., 104, and 204) include introducing a nitrogen reactant into the reaction chamber, such as during step 108 of cyclical deposition process 104, and during sub-step 308 of cyclical deposition process 204. In various embodiments the nitrogen reactant comprises a nitridation agent.

In some embodiments the nitrogen reactant is selected from ammonia (NH₃), hydrazine (N₂H₄), other nitrogen and hydrogen-containing gases (e.g., a mixture of nitrogen gas and hydrogen gas), and the like. In some examples the nitrogen reactant can include or consist of nitrogen and hydrogen. In some examples the nitrogen reactant does not include diatomic nitrogen. In some examples the nitrogen reactant comprises a substituted hydrazine compound. In such examples the substituted hydrazine compound may comprise an alkyl-hydrazine selected from C₄H₉N₂H₃, CH₃NHNH₂, C₂H₈N₂, and C₄H₁₂N₂. In some examples the substituted hydrazine compound may comprise one or more of 1,1-diethylhydrazine, 1-ethyl-1-methylhydrazine, isopropylhydrazine, phenylhydrazine, 1,1-diphenylhydrazine, 1,2-diphenylhydrazine, N-methyl-N-phenylhydrazine, 1,1-dibenzylhydrazine, 1,2-dibenzylhydrazine, 1-ethyl-1-phenylhydrazine, 1-methyl-1-(m-tolyl)hydrazine, and 1-ethyl-1-(p-tolyl)hydrazine. In some embodiments the nitrogen reactant comprises one or more of ammonia, a hydrazine, or an amine. In some embodiments the nitrogen reactant comprises or consists essentially of ammonia (NH₃).

The cyclical deposition processes of the present disclosure (e.g., 104, and 204) include introducing a reducing agent comprising a cyclic compound into the reaction chamber, such as during step 110 of cyclical deposition process 104, and during sub-step 410 of cyclical deposition process 204. In various embodiments the cyclic compound (or ring compound) comprises a cyclic hydrocarbon.

In various embodiments the cyclic compound comprises carbon, hydrogen, and at least two unsaturated carbon-carbon bonds. In some embodiments, the cyclic compound comprises a cyclic hydrocarbon having at least two unsaturated carbon-carbon bonds. In some embodiments the cyclic compound comprises a 6-member ring comprising carbon, hydrogen, and at least two double bonds between the constituent carbons. In some embodiments the cyclic compound comprises a 6-member ring comprising carbon, hydrogen, and one or more addition elements, such as, nitrogen, for example.

In accordance with examples of the disclosure, the cyclic compound may comprise a cyclodiene compound. In some embodiments, the cyclic compound comprises a cyclohexadiene compound. In some embodiments the cyclic compound comprises a cyclohexadiene compound selected from 1,4-cyclohexadiene and 1,3-cyclohexadiene.

In some embodiments the cyclic compound comprises a cyclodiene compound comprising one or more substituents. For example, the substituents may be selected from alkyls, aminos, dimethylaminos, and alkoxyls. In some embodiments the cyclic compound comprises a cyclodiene compound comprising one or more alkyl substituents. In some embodiments the cyclic compound comprises a cyclic alkadiene. In some examples the cyclic compound comprises 1-methyl-1,4-cyclohexadiene.

In various embodiments the cyclic compound comprises one or more of 1,4-cyclohexadiene, 1,3-cyclohexadiene, and 1-methyl-1,4-cyclohexadiene. In some embodiments the cyclic compound is 1,4-cyclohexadiene. In some embodiments the cyclic compound is 1,3-cyclohexadiene. In some embodiments the cyclic compound is 1-methyl-1,4-cyclohexadiene.

In accordance with examples of the disclosure, the cyclic compound may comprise a polycyclic hydrocarbon compound. In some embodiments the polycyclic hydrocarbon compound comprises a benzoid. In some embodiments the polycyclic hydrocarbon compound comprises a tetralin. In some embodiments the polycyclic hydrocarbon compound comprises an anthracene. In some embodiments the polycyclic hydrocarbon compound is selected from 1,2,3,4-tetrahydronaphthalene and 9,10-Dihydroanthracene.

In various embodiments the cyclic compound does not contain silicon (Si). In various embodiments the cyclic compound does not contain an alkylsilyl substituent.

The various embodiments include methods of forming structures including one or more metal nitride layers. In such embodiments the metal nitride layers are deposited by the methods previously described above, e.g., by the cyclical deposition processes 104 and 204.

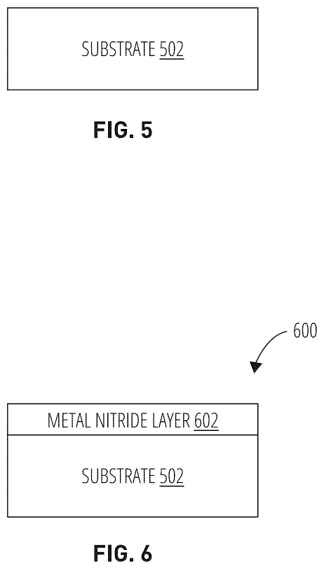

In accordance with examples of the disclosure FIG. 5 illustrates a substrate 502 as described in detail above and FIG. 6 illustrates a structure 600 comprising the substrate 502 with a metal nitride layer 602 disposed on the surface of the substrate and deposited by the methods described above.

In some embodiments the metal nitride layer 602 comprises a transition metal nitride layer. In some examples the metal nitride layer 602 comprises or consists essentially of a molybdenum nitride layer. In some examples the metal nitride layer 602 comprises or consists essentially of a titanium nitride layer. In some examples the metal nitride layer 602 comprises or consists essentially of a hafnium nitride layer. In some examples the metal nitride layer 602 comprises or consists essentially of a niobium nitride layer.

In some embodiments the metal nitride layer 602 has an average layer thickness of less than 10 nanometers (nm), less than 8 nm, less than 6 nm, less 5 nm, less than 4 nm, less than 3 nm, less than 2, less than 1 nm, or between 1 nm and 10 nm. In some embodiments the metal nitride layer 602 has an average thickness non-uniformity (NU %) of less than 10%, less than 8%, less than 6 %, less than 4 %, less than 2%, less than 1%, or between 1% and 10%.

In some embodiments the metal nitride layer 602 has an electrical resistivity (μΩ·cm) of less than 3000 μΩ·cm, less than 2000 μΩ·cm, less than 1000 μΩ·cm, less than 750 μΩ·cm, less than 500 μΩ·cm. In some embodiments the metal nitride layer 602 has an average layer thickness of less than 10 nanometers (nm), less than 8 nm, less than 6 nm, less 5 nm, less than 4 nm, less than 3 nm, less than 2, less than 1 nm, or between 1 nm and 10 nm, and an electrical resistivity of less than less than 1000 μΩ·cm, less than 750 μΩ·cm, less than 500 μΩ·cm, or between 500 μΩ·cm and 1000 μΩ·cm.

In accordance with examples of the disclosure, the substrate 502 may further comprise a surface metal oxide layer (not illustrated) having an initial average layer thickness. In some embodiments the metal nitride layer 602 may be deposited directly on the surface metal oxide layer by the cyclical deposition methods described above, e.g., cyclical deposition process 104 and 204. In some embodiments the deposition of the metal nitride layer 602 directly on the surface metal oxide layer does not remove, or significantly remove, a thickness of the surface metal oxide layer.

The various embodiments include methods of forming structures including a metal nitride layer and a metal nitride interlayer. In such embodiments the introduction of the cyclic compound into the reaction chamber can be controlled to tailor the stoichiometry of the metal nitride layer that is deposited on the substrate to a desired stoichiometry. For example, in some embodiments it may be beneficial to initially deposit a first metal nitride layer comprising a first stoichiometry on the substrate (referred to herein as a metal nitride interlayer), followed subsequently by depositing a second metal nitride layer comprising a second stoichiometry on the metal nitride interlayer, the second stoichiometry being different to the first stoichiometry. In some examples the initial metal nitride interlayer may comprise a first stoichiometry which is less susceptible to oxidation than a subsequent metal nitride layer, comprising a second stoichiometry, deposited on, or directly on, the metal nitride interlayer. In such examples the metal nitride interlayer may form an interface layer (or capping layer) between the underlying material and the metal nitride layer disposed on the metal nitride interlayer. As a non-limiting example, the underlying material may comprise a metal oxide layer and the metal nitride interlayer may form an interface layer between the metal oxide layer and the subsequent metal nitride layer formed on the metal nitride interlayer.

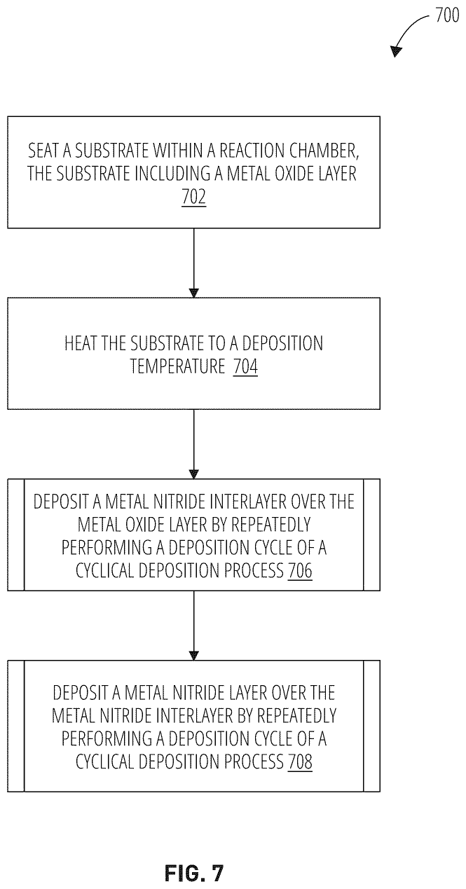

In accordance with examples of the disclosure FIG. 7 illustrates a method 700 of forming a structure. In brief method 700 comprises seating a substrate within a reaction chamber, the substrate including a metal oxide layer (step 702), heating the substrate to a deposition temperature (step 704), depositing a metal nitride interlayer over the metal oxide layer by a cyclical deposition process (step 706), and depositing a metal nitride layer over the metal nitride interlayer by a cyclical deposition process (step 708).

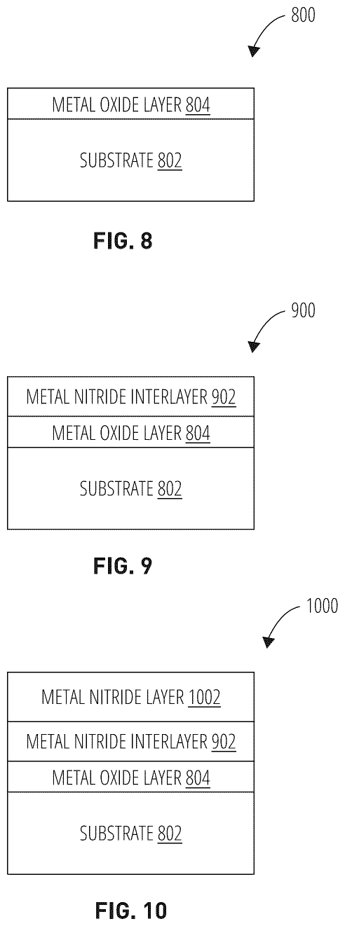

In accordance with examples of the disclosure the substrate may comprise one or more of those previously described above. For example, FIG. 8 illustrates a structure 800 including a substrate 802 (similar to or the same as that previously described with reference to substrate 502 of FIG. 5). In addition, the structure 800 includes a metal oxide layer 804 formed over the substrate 802. As illustrated in FIG. 8 the metal oxide layer 804 is disposed over the substrate 802. In some embodiments the metal oxide layer 804 comprises a dielectric layer. In some embodiments the metal oxide layer 804 comprises a high dielectric constant (high-k) layer.

In some embodiments, the metal oxide layer 804 may comprise a hafnium containing metal oxide layer. In some examples the hafnium containing metal oxide layer may comprises a hafnium oxide high-k layer. In some examples the hafnium containing metal oxide layer may comprise a ternary hafnium oxide high-k layer. In some examples the metal oxide layer may comprise hafnium oxide (HfO₂), doped HfO₂, hafnium zirconium oxide (HfZrO), doped HfZrO, or the like.

In some embodiments, the metal oxide layer 804 may comprise a high-k metal oxide layer such as titanium oxide, zirconium oxide, aluminum oxide, barium-strontium-titanate, erbium oxide, hafnium silicate, lanthanum oxide, niobium oxide, lead-zirconium-titanate, strontium titanate, tantalum oxide, titanium oxide, zirconium oxide, or other high-k or ultra-high-k metal oxide (e.g., with k-values greater than about 40).

In accordance with examples of the disclosure, the method 700 includes seating the substrate in a reaction chamber (step 702) and heating the substrate to a deposition temperature (step 704). In such examples the reaction chamber may comprise any one or more of those previously described above. In addition, in such examples, the substrate may be heated to a deposition temperature as described previously with reference to method 100 of FIG. 1. As a non-limiting example, the substrate may be seated within a reaction chamber configured for cyclical deposition process (e.g., configured for ALD processes or ALD-like processes) and the substrate may be heated to a deposition temperature between 350° C. and 500° C.

In accordance with examples of the disclosure, the method 700 comprises depositing a metal nitride interlayer over the metal oxide layer by repeatedly performing a cyclical deposition process (step 706). In such examples the metal nitride interlayer may be deposited prior to the deposition of a metal nitride layer on, or directly on, the metal nitride interlayer. In some embodiments, the method 700 comprises depositing the metal nitride interlayer directly on the metal oxide layer prior to depositing the metal nitride layer directly on the metal nitride interlayer.

In accordance with examples of the disclosure, the metal nitride interlayer can be deposited by an atomic layer deposition process (referred to herein as a second atomic layer deposition process). In such examples the second atomic layer deposition process employed for depositing the metal nitride interlayer may comprise sequentially and alternating contacting the substrate with a metal precursor and a nitrogen reactant. In some embodiments the second atomic layer deposition process may be the same, similar, or substantially similar to the first sub-cycle 210 as described above with reference to FIG. 3. In such embodiments the metal precursor and the nitrogen reactant can include any one or more of the metal precursors and nitrogen reactants as described above with reference to the cyclical deposition process 104 and the cyclical deposition process 204. In some embodiments the second atomic layer deposition process may exclude the introduction of the reducing agent comprising the cyclic compound.

FIG. 9 illustrates a structure 900 which comprises the previous structure 800 (FIG. 8) after the deposition of the metal nitride interlayer by a second atomic layer deposition process. As illustrated in FIG. 9 the structure 900 comprises the substrate 802, the metal oxide layer 804, and additional the metal nitride interlayer 902 deposited on, or directly on, the metal oxide layer 804. In such examples the metal nitride interlayer 902 can form an interface layer between the metal oxide layer 804 and a subsequent metal nitride layer deposited on, or directly on the metal nitride interlayer 902, as describe below.

In accordance with examples of the disclosure, the method 700 comprises depositing a metal nitride layer over the metal oxide layer, and particular on, or directly on, the metal nitride interlayer disposed on the metal oxide layer (step 708). In such examples the metal nitride layer may be deposited a cyclical deposition process comprising an atomic layer deposition process (referred to herein as the first atomic layer deposition process). In such examples the first atomic layer deposition process employed for depositing the metal nitride layer on, or directly one, the metal nitride interlayer may comprise one or more of the cyclical deposition processes previously described above with reference to FIG. 1, FIG. 2, and FIG. 3, such as, for example, the cyclical deposition process 104 and 204. In some examples the first atomic layer deposition process may comprise repeatedly performing a deposition cycle of a first atomic layer deposition process, where each deposition cycle comprises: initially contacting the substrate with a metal precursor, after contacting the substrate with the metal precursor, contacting the substrate with the nitrogen reactant, and after contacting the substrate with the nitrogen reactant, contacting the substrate with a reducing agent comprising a cyclic diene compound selected from 1,4-cyclohexadiene, 1,3-cyclohexadiene, and 1-methyl-1,4-cyclohexadiene.

FIG. 10 illustrates a structure 1000 which comprises the previous structure 900 (FIG. 9) after the deposition of the metal nitride layer by the first atomic layer deposition process. As illustrated in FIG. 10 the structure 1000 comprises the substrate 802, the metal oxide layer 804, the metal nitride interlayer 902 deposited on, or directly on, the metal oxide layer 804, and in addition the metal nitride layer 1002 deposited on, or directly on, the metal nitride interlayer 902. In such examples the metal nitride interlayer 902 can form an interface layer between the metal oxide layer 804 and the metal nitride layer 1002 such that the metal nitride interlayer 902 is disposed between, or directly between, the metal oxide layer 804 and the metal nitride layer 1002.

In accordance with examples of the disclosure, both the metal nitride interlayer 902 and the metal nitride layer 1002 may comprise a metal nitride material comprising a metal selected from the transition metals, including but not limited to, titanium, zirconium, hafnium, vanadium, niobium, tantalum, chromium, molybdenum, and tungsten.

In some embodiments both the metal nitride interlayer 902 and the metal nitride layer 1002 may comprise or consist essentially of a titanium nitride. In some embodiments both the metal nitride interlayer 902 and the metal nitride layer 1002 may comprise or consist essentially of a molybdenum nitride. In some embodiments both the metal nitride interlayer 902 and the metal nitride layer 1002 may comprise or consist essentially of a hafnium nitride. In some embodiments both the metal nitride interlayer 902 and the metal nitride layer 1002 may comprise or consist essentially of a niobium nitride.

In accordance with examples of the disclosure the metal nitride layer 1002 may comprise a material having a first conductivity and the metal nitride interlayer 902 may comprise a material having a second conductivity, wherein the first conductivity is different to the first conductivity. In one example the metal nitride layer 1002 may comprise a conductive layer and metal nitride interlayer 902 may comprise an insulating layer. In another example the metal nitride layer 1002 may comprise a conductive layer and metal nitride interlayer 902 may comprise a semiconducting layer. In another example the metal nitride layer 1002 may comprise an insulating layer and metal nitride interlayer 902 may comprise a conductive layer. In another example the metal nitride layer 1002 may comprise a semiconducting layer and metal nitride interlayer 902 may comprise a conductive layer. In various examples of the disclosure the metal nitride layer 1002 may comprise a conductive layer and the metal nitride interlayer 902 may comprise an insulating layer.

In some embodiments, the metal nitride interlayer 902 may comprise an insulating hafnium nitride and the metal nitride layer 1002 may comprise a conducting hafnium nitride. In some embodiments, the metal nitride interlayer 902 may comprise an insulating molybdenum nitride and the metal nitride layer 1002 may comprise a conducting molybdenum nitride. In some embodiments, the metal nitride interlayer 902 may comprise an insulating titanium nitride and the metal nitride layer 1002 may comprise a conducting titanium nitride. In some embodiments, the metal nitride interlayer 902 may comprise an insulating niobium nitride and the metal nitride layer 1002 may comprise a conducting niobium nitride.

In accordance with examples of the disclosure the metal nitride layer 1002 may comprise a metal nitride comprising or consisting essentially of a first stoichiometry and the metal nitride interlayer 902 may comprise a metal nitride comprising or consisting of a second stoichiometry where the first stoichiometry is different to the second stoichiometry. As a non-limiting example, the metal nitride layer 1002 may comprise or consist essentially of a first hafnium nitride layer having a first stoichiometry and the metal nitride interlayer 902 may comprise or consist essentially of a second hafnium nitride layer having a second stoichiometry, where the first stoichiometry is different to the second stoichiometry. In such non-limiting examples, the first hafnium nitride layer (i.e., the metal nitride layer 1002) may comprise or consist essentially of HfN and the second hafnium nitride layer (i.e., the metal nitride interlayer 902) may comprise or consist essentially of Hf₃N₄. As a further non-limiting example, the metal nitride layer 1002 may comprise or consist essentially of a first molybdenum nitride layer having a first stoichiometry and the metal nitride interlayer 902 may comprise or consist essentially of a second molybdenum nitride layer having a second stoichiometry, where the first stoichiometry is different to the second stoichiometry. As a further non-limiting example, the metal nitride layer 1002 may comprise or consist essentially of a first titanium nitride layer having a first stoichiometry and the metal nitride interlayer 902 may comprise or consist essentially of a second titanium nitride layer having a second stoichiometry, where the first stoichiometry is different to the second stoichiometry.

In some embodiments an additional conducting layer may be deposited on, or directly on the metal nitride layer 1002. As a non-limiting examples, a titanium nitride layer may be deposited by atomic layer deposition process on or directly on the metal nitride layer 1002.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method for depositing a metal nitride layer on a substrate seated in a reaction chamber by a cyclical deposition process including one or more repeated deposition cycles, each deposition cycle comprising:
(a) initially introducing a metal precursor into the reaction chamber;
(b) introducing a nitrogen reactant into the reaction chamber; and
(c) introducing a reducing agent comprising a cyclic compound into the reaction chamber,
wherein step (c) is either performed after step (b) or step (c) is performed concurrently with step (b).

2. The method of claim 1, wherein the cyclical deposition process is an atomic layer deposition process and each deposition cycle comprises:
(a) initially contacting the substrate with the metal precursor;
after step (a), (b) contacting the substrate with the nitrogen reactant; and
after step (b), (c) contacting the substrate with the cyclic compound.

3. The method of claim 1, wherein the cyclical deposition process is an atomic layer deposition process and each deposition cycle comprises:
(a) initially contacting the substrate with the metal precursor; and
after step (a), (b)(c) concurrently contacting the substrate with the nitrogen reactant and the cyclic compound.

4. The method of claim 1, wherein the cyclical deposition process is an atomic layer deposition process and each deposition cycle comprises a deposition super-cycle, each deposition super-cycle comprising:
performing one or more first sub-cycles comprising:
contacting the substrate with the metal precursor; and
contacting the substrate with the nitrogen reactant; and
performing one or more second sub-cycles comprising:
contacting the substrate with the cyclic compound.

5. The method of claim 1, wherein the cyclic compound comprises a cyclic diene compound.

6. The method of claim 5, wherein the cyclic diene compound is selected from 1,4-cyclohexadiene, 1,3-cyclohexadiene, and 1-methyl-1,4-cyclohexadiene.

7. The method of claim 1, wherein the cyclic compound comprises a polycyclic hydrocarbon compound.

8. The method of claim 7, wherein the polycyclic hydrocarbon compound is selected from 1,2,3,4-tetrahydronaphthalene and 9,10-Dihydroanthracene.

9. The method of claim 1, wherein the metal precursor is selected from a titanium precursor, a molybdenum precursor, a hafnium precursor, and a niobium precursor.

10. The method of claim 1, wherein the cyclical deposition process is performed at a deposition temperature between 350° C. and 500° C.

11. A method for thermally depositing a metal nitride layer on a substrate, the method comprising:
heating the substrate to a deposition temperature between 350° C. and 500° C.; and
repeatedly performing a deposition cycle of an atomic layer deposition process, each deposition cycle comprising:
(a) initially contacting the substrate with a transition metal precursor;
after contacting the substrate the transition metal precursor, (b) contacting the substrate with a nitrogen reactant; and
after contacting the substrate with the nitrogen reactant, (c) contacting the substrate with a reducing agent comprising a cyclic diene compound selected from 1,4-cyclohexadiene, 1,3-cyclohexadiene, and 1-methyl-1,4-cyclohexadiene.

12. The method of claim 11, wherein the transition metal precursor is selected from a titanium halide precursor, and a molybdenum halide precursor.

13. The method of claim 12, wherein the molybdenum halide precursor comprises a molybdenum oxyhalide precursor.

14. A method of forming a semiconductor structure, the method comprising:
seating a substrate within a reaction chamber, the substrate including a metal oxide layer;
heating the substrate to a deposition temperature between 350°C. and 500° C.; and
depositing a metal nitride layer over the metal oxide layer by repeatedly performing a deposition cycle of an atomic layer deposition process, each deposition cycle comprising:
(a) initially contacting the substrate with a metal precursor;
after contacting the substrate the metal precursor, (b) contacting the substrate with a nitrogen reactant; and
after contacting the substrate with the nitrogen reactant, (c) contacting the substrate with reducing agent comprising a cyclic diene compound selected from 1,4-cyclohexadiene, 1,3-cyclohexadiene, and 1-methyl-1,4-cyclohexadiene.

15. The method of claim 14, further comprising depositing a metal nitride interlayer directly on the metal oxide layer prior to depositing the metal nitride layer directly on the metal nitride interlayer.

16. The method of claim 15, wherein the metal nitride interlayer is deposited by a second atomic layer deposition process comprising sequentially and alternating contacting the substrate with the metal precursor and the nitrogen reactant.

17. The method of claim 16, wherein the metal nitride layer is a conductive layer and the metal nitride interlayer is an insulating layer.

18. The method of claim 16, wherein the metal nitride layer has a first stoichiometry and the metal nitride interlayer has a second stoichiometry, wherein the first stoichiometry and the second stoichiometry are different from each other.

19. The method of claim 17, wherein the metal nitride layer comprises a first hafnium nitride layer and the metal nitride interlayer comprise a second hafnium nitride layer.

20. The method of claim 19, wherein the first hafnium nitride layer has a HfN stoichiometry and the second hafnium nitride layer has a Hf₃N₄ stoichiometry.
